(19) United States
(12) Patent Application Publication
(10) Pub. No.: US 2025/0054900 A1
(43) Pub. Date: Feb. 13, 2025

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Chun-Yen Lan, Hsinchu County (TW); Chih-Chien Pan, Taipei City (TW); Pu Wang, Hsinchu City (TW); Li-Hui Cheng, New Taipei City (TW); Ying-Ching Shih, Hsinchu City (TW); Yu-Wei Lin, New Taipei City (TW)

(73) Assignee: Taiwan Semiconductor Manufacturing Company, Ltd., Hsinchu (TW)

(21) Appl. No.: 18/366,620

(22) Filed: Aug. 7, 2023

(51) Int. Cl. H01L 23/00; H01L 23/498; H01L 23/538; H01L 25/00; H01L 25/065; H01L 25/16

(52) U.S. Cl. CPC H01L 24/33; H01L 23/49811; H01L 23/5385; H01L 23/5386; H01L 24/16; H01L 24/32; H01L 24/73; H01L 25/0655; H01L 25/162; H01L 25/165; H01L 25/50; H01L 2224/16225; H01L 2224/26145; H01L 2224/32225; H01L 2224/32245; H01L 2224/33519; H01L 2224/73204; H01L 2224/73253; H01L 2225/065; H01L 2924/16235; H01L 2924/17151; H01L 2924/173

(57) ABSTRACT

A package structure includes a circuit substrate, a package unit, a thermal interface material and a cover. The package unit is disposed on and electrically connected with the circuit substrate. The package unit includes a first surface facing the circuit substrate and a second surface opposite to the first surface. A underfill is disposed between the package unit and the circuit substrate, surrounding the package unit and partially covering sidewalls of the package unit. The cover is disposed over the package unit and over the circuit substrate. An adhesive is disposed on the circuit substrate and between the cover and the circuit substrate. The thermal interface material includes a metal-type thermal interface material and is disposed between the cover and the package unit. The thermal interface material physically contacts the second surface and the sidewalls of the package unit and physically contacts the underfill.

### BACKGROUND

Integration of multiple semiconductor devices and electronic components requires advanced packaging and assembling techniques.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 6 are schematic cross-sectional views of structures produced at various stages of a manufacturing method of a semiconductor package according to some embodiments of the present disclosure.

FIG. 7A is a schematic cross-sectional view of a portion of the semiconductor package according to some embodiments of the present disclosure.

FIG. 7B and FIG. 7C are schematic top views of the semiconductor package according to some embodiments of the present disclosure.

FIG. 7D is a schematic perspective view of an exemplary structure of the thermal interface material according to some embodiments of the present disclosure.

FIG. 8 is a schematic cross-sectional view of a semiconductor package according to some embodiments of the present disclosure.

FIG. 9 to FIG. 11 are schematic cross-sectional views of structures produced at various stages of a manufacturing method of a semiconductor package according to some embodiments of the present disclosure.

FIG. 12A is a schematic cross-sectional view of a portion of the semiconductor package according to some embodiments of the present disclosure.

FIG. 12B is a schematic top view of the semiconductor package according to some embodiments of the present disclosure.

FIG. 13A and FIG. 13B are schematic cross-sectional views of portions of semiconductor packages according to some embodiments of the present disclosure.

FIG. 14 and FIG. 15 are schematic cross-sectional views of semiconductor packages according to some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

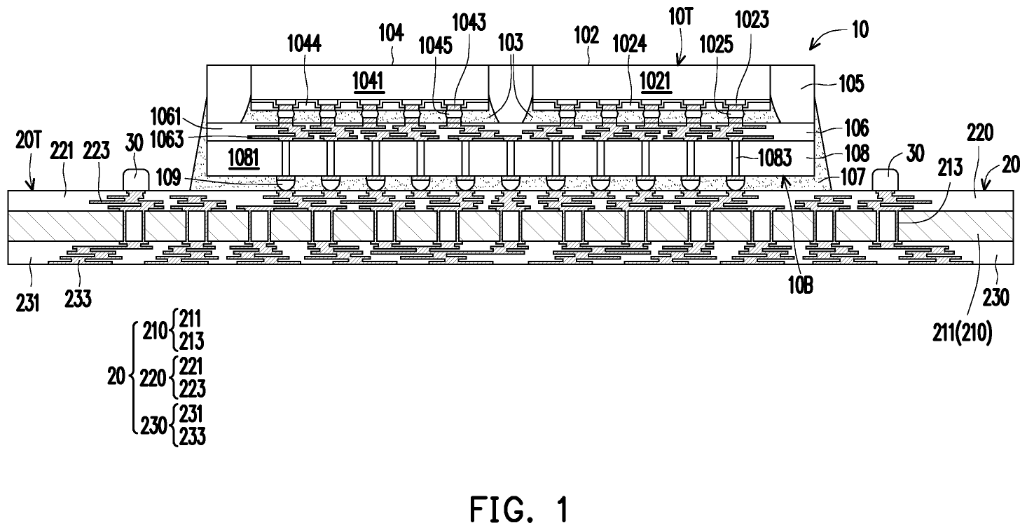

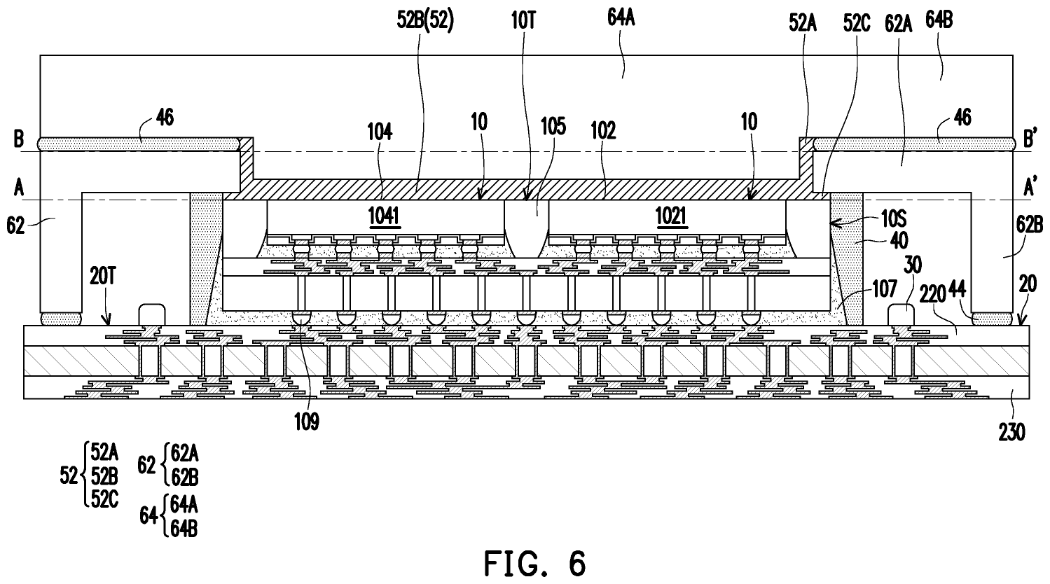

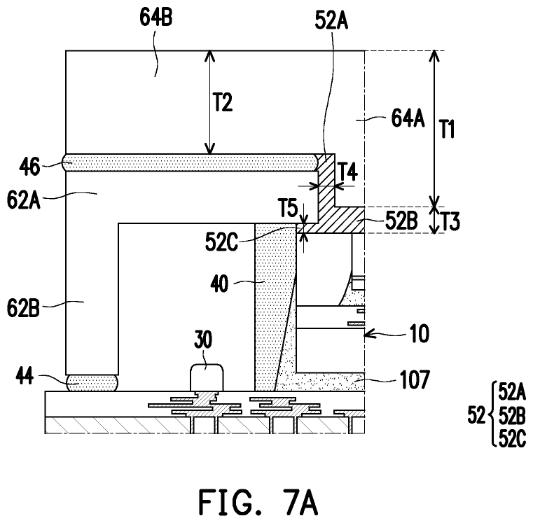

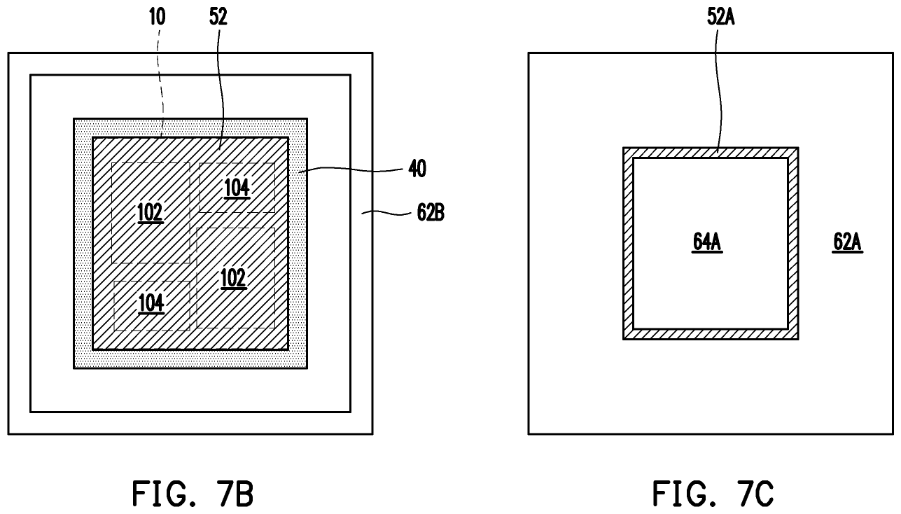

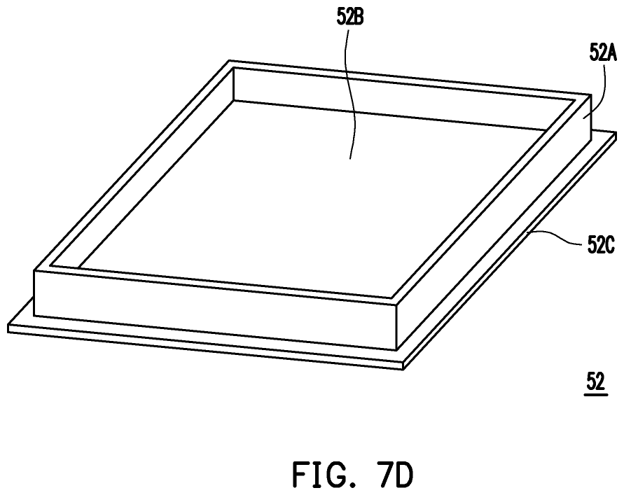

FIG. 1 to FIG. 6 are schematic cross-sectional views of structures produced at various stages of a manufacturing method of a semiconductor package according to some embodiments of the present disclosure. FIG. 7A is a schematic cross-sectional view of a portion of the semiconductor package as shown in FIG. 6. FIG. 7B and FIG. 7C are schematic top views of the semiconductor package as shown in FIG. 6 along the cross-section lines A-A′ and B-B′.

Referring to FIG. 1, in some embodiments, one or more package units 10 and a circuit substrate 20 are provided. In some embodiments, the circuit substrate 20 includes a core layer 210 and build-up layers 220, 230 disposed on opposite sides of the core layer 210. The core layer 210 may include a dielectric layer 211 having plated through holes 213 which extend cross the dielectric layer 211 from side to side. In some embodiments, the plated through holes 213 are electrically conductive and may be partially filled or fully filled. In some embodiments, each build-up layer 220 or 230 respectively includes a dielectric layer 221 or 231 and conductive patterns 223 or 233 embedded in the corresponding dielectric layer 221 or 231 and providing electrical connection between opposite sides of the corresponding dielectric layer 221 or 231. In some embodiments, the circuit substrate 20 with the build-up layers 220, 230 provides electrical connection for devices or components bonded to both sides (double side connection). In some embodiments, the circuit substrate 20 provided may have multiple core layers or stacks for further connection. Although it is not shown in the figure, it is understood that the circuit substrate 20 may be carried or supported by a carrier or a carrying frame.

Referring to FIG. 1, in some embodiments, one or more package units 10 (only one is shown) are mounted onto and connected to the top surface 20T of the circuit substrate 20 (e.g., the top side of the build-up layer 220). Also, in some embodiments, a plurality of passive components 30 are mounted onto and bonded to the top surface 20T of the circuit substrate 20 and beside the package unit(s) 10. In some embodiments, the passive components 30 include or are capacitors, inductors, resistors, diodes, transformers or combinations thereof. In some embodiments, the package unit 10 includes or is a chip-on-wafer-on-substrate (CoWoS) package, and the package unit 10 is bonded to and electrically connected with the circuit substrate 20 through the electrical connectors 109. In some other embodiments, the package unit 10 may be a multi-chip stacked package, a chip on wafer (CoW) package, an integrated fan-out (InFO) package, a three-dimensional integrated circuit (3DIC) package, or a combination thereof.

In some embodiments, the package unit 10 includes two, three or more semiconductor dies, and the semiconductor die 102 and 104 are shown in the cross-sectional view of the figure as an example. In some embodiments, each semiconductor die 102 includes a semiconductor substrate 1021, contact pads 1023 and a passivation layer 1024. In some embodiments, the contact pads 1023 are formed on the semiconductor substrate 1021, and the passivation layer 1024 covers the semiconductor substrate 1021 with the contact pads 1023 exposed from the passivation layer 1024. In some embodiments, each semiconductor die 104 includes a semiconductor substrate 1041, contact pads 1043 and a passivation layer 1044. In some embodiments, the passivation layer 1044 covers the semiconductor substrate 1041 and surrounds the contact pads 1043 that are formed on the semiconductor substrate 1041 but the contact pads 1043 are exposed from the passivation layer 1044.

In some embodiments, the semiconductor substrates 1021, 1041 of the semiconductor dies 102, 104 include or are made of semiconductor materials, such as semiconductor materials of the groups III-V of the periodic table, and include active components (e.g., transistors or the like) and optionally passive components (e.g., resistors, capacitors, inductors, or the like) formed therein. In some embodiments, any semiconductor die(s) of the package unit 10 may have similar features as the ones just discussed. In some embodiments, the semiconductor dies 102, 104 may independently be or include a logic die, such as a central processing unit (CPU) die, a graphic processing unit (GPU) die, a micro control unit (MCU) die, an input-output (I/O) die, a baseband (BB) die, a system-on-chip (SoC) die, a large-scale integrated circuit (LSI) die, or an application processor (AP) die. In some embodiments, one or more semiconductor dies 102, 104 may independently be or include memory dies such as high bandwidth memory (HBM) dies. The disclosure is not limited by the types of dies included in the package unit 10.

Referring to FIG. 1, in some embodiments, the semiconductor dies 102, 104 are electrically connected to an interposer 108 through a redistribution layer 106. In some embodiments, the interposer 108 includes a semiconductor substrate 1081 and through semiconductor vias (TSVs) 1083 for dual-side electrical connection. It is understood that the semiconductor substrate 1081 may be similarly to what was previously discussed with reference to the semiconductor substrates of the semiconductor dies 102, 104. In some embodiments, the redistribution layer 106 disposed on the interposer 108 includes a dielectric layer 1061 and conductive patterns 1063 embedded therein. In some embodiments, the semiconductor dies 102, 104 are bonded to the redistribution layer 106 through micro-connectors 1025, 1045. In some embodiments, through the TSVs 1083, the semiconductor dies 102, 104 are electrically connected to the circuit substrate 20 through the electrical connectors 109 located between the interposer 108 and the circuit substrate 20. For simplicity, for the redistribution layer 106, the dielectric layer is illustrated as a single dielectric layer and the conductive patterns are illustrated as embedded in the dielectric layer, nevertheless, from the perspective of the manufacturing process, the dielectric layer may be constituted by two or more dielectric layers, and the configuration of the conductive patterns may be adjusted or modified depending on routing requirements. In some embodiments, the material of the dielectric layer 1061 includes polyimide, epoxy resin, acrylic resin, phenol resin, benzocyclobutene (BCB), polybenzoxazole (PBO), or any other suitable polymer-based dielectric material, and the dielectric layer 1061 may be formed by suitable fabrication techniques such as spin-on coating, chemical vapor deposition (CVD), lamination or the like. In some embodiments, the materials of the conductive patterns 1063 include aluminum, titanium, copper, nickel, tungsten, or alloys thereof. In some embodiments, a material of the TSVs 1083 includes one or more metal material such as copper, titanium, tungsten, aluminum, combinations thereof, or the like.

In some embodiments, the semiconductor dies 102, 104 are disposed with the active surfaces (the surfaces exposing the contact pads 1023, 1043) facing the interposer 108, and the micro-connectors 1025, 1045 located there-between are or include micro-bumps or metallic pillars. In FIG. 1, in some embodiments, after the semiconductor dies 102, 104 are bonded to the redistribution layer 106, an underfill 103 is formed between the semiconductor dies 102, 104 and the redistribution layer 106 surrounding the micro-connectors 1025, 1045 to protect the micro-connectors 1025, 1045 against thermal or physical stresses and secure the electrical connection of the semiconductor dies 102, 104 to the interposer 108. In some embodiments, the underfill 103 is formed by capillary underfill filling (CUF). In some embodiments, as shown in FIG. 1, the underfill 103 is formed into multiple underfill portions with each portion respectively securing the semiconductor die 102 or 104 and the corresponding micro-connectors 1025 or 1045. In some alternative embodiments, a single common underfill (not shown) may extend below the semiconductor dies 102, 104, depending on the spacing and relative positions of the dies over the interposer.

Referring to FIG. 1, an encapsulant 105 is formed over the redistribution layer 106 and the interposer 108 wrapping the semiconductor dies 102, 104 and the underfill(s) 103. In some embodiments, the encapsulant 105 includes a molding compound, a resin (such as epoxy resin or phenolic resin), or the like. In some embodiments, the encapsulant 105 laterally encapsulated the semiconductor dies 102, 104 leaving the backside surfaces of the semiconductor dies 102, 104 exposed. That is, the backside surface 10T of the package unit 10 is constituted by the backside surfaces of the semiconductor dies 102, 104 and the encapsulant 105. The opposite surface 10B of the package unit 10 opposing to the backside surface 10T is the connection surface or active surface of the package unit.

In some embodiments, the electrical connectors 109 disposed between the package unit(s) 10 and the build-up layer 220 of the circuit substrate 20 include or are controlled collapse chip connection (C4) bumps. In some embodiments, another underfill 107 is disposed between the package unit 10 and the circuit substrate 20 to protect the connectors 109 from thermal and mechanical stresses and securing the package unit(s) 10.

In FIG. 1 only one package unit 10 with two semiconductor dies 102, 104 are shown on the interposer 108 for simplicity, but the disclosure is not limited thereto. Furthermore, whilst the process is currently being illustrated for a CoWoS package, the disclosure is not limited to the package structure shown in the drawings, and other types of semiconductor package such as integrated fan-out (InFO) packages, package-on-packages (POP), etc., are also meant to be covered by the present disclosure and to fall within the scope of the appended claims.

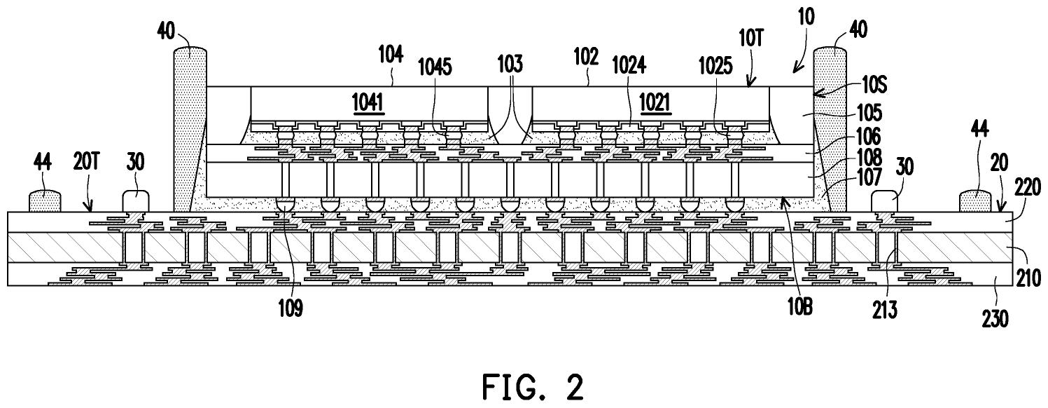

Referring to FIG. 2, in some embodiments, an adhesive 44 is applied and disposed on the top surface 20T of the circuit substrate 20, along the outer periphery of the circuit substrate 20. In some embodiments, the adhesive 44 forms a frame following the profile of the outer periphery of the circuit substrate 20. For example, if the circuit substrate 20 has a rectangular footprint from the top view, the adhesive 44 may have the shape of a rectangular frame. Similarly, if the circuit substrate 20 has a circular footprint, the adhesive 44 may have the shape of a circular frame. In some embodiments, the adhesive 44 is formed into a continuous frame. In some embodiments, the adhesive 44 is formed into multiple portions spaced apart from each other on the circuit substrate 20, arranged as a frame but with gaps between the multiple portions exposing the circuit substrate 20.

Referring to FIG. 2, in some embodiments, a dielectric dam 40 is formed beside the package unit 10. In some embodiments, the dielectric dam 40 is formed on the top surface 20T of the circuit substrate 20 along the outer periphery of the package unit 10. In FIG. 2, in some embodiments, the dielectric dam 40 covers the underfill 107 and covers the sidewalls 10S of the package unit 10. In some embodiments, as the underfill 107 does not fully cover the sidewalls 10S of the package unit 10, the dielectric dam 40 abuts (in direct contact with) the upper sidewalls of the package unit 10. In some embodiments, the dielectric dam 40 has a height larger than the package unit 10, or the top of the dielectric dam 40 is higher than the backside surface 10T of the package unit 10. In some embodiments, the dielectric dam 40 forms a continuous frame wall following the profile of the outer periphery of the package unit 10 (e.g. in FIG. 7B). The dielectric dam may function to limit the distribution and span of the to-be-formed thermal interface material (TIM). Also, the dielectric dam 40 located between the package unit 10 and the surrounding passive components 30 physically isolate the package unit 10 and the passive components 30.

In some embodiments, the dielectric dam 40 and the adhesive 44 are formed from the same adhesive material and formed from the same dispensing process. In some embodiments, the dielectric dam 40 and the adhesive 44 are formed from different adhesive materials. For example, the material of the dielectric dam 40 and the material of the adhesive 44 are independently selected from a thermo-curable adhesive, a photocurable adhesive, a thermally conductive adhesive, a thermosetting resin, a waterproof adhesive, a lamination adhesive, or a combination thereof. In some embodiments, the dielectric dam 40 is made from a polymeric dielectric material such as epoxy resins, silicon-containing resins or acrylic resins. In some embodiments, the dielectric dam 40 includes an epoxy resin, and the adhesive 44 includes a thermally conductive adhesive. According to the type of material(s) used, the dielectric dam 40 or adhesive 44 may be formed by dispensing, lamination, printing, or any other suitable technique.

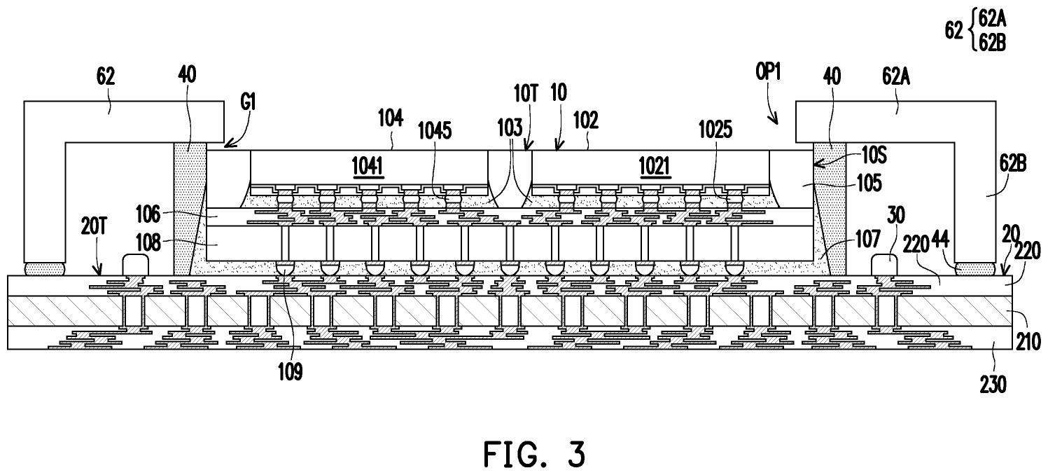

Referring to FIG. 3, a support 62 is disposed on the adhesive 44 over the circuit substrate 20. In some embodiments, after mounting the support 62 to the circuit substrate 20, a thermal process or a pre-curing process is performed so that the support 62 is fixed to the circuit substrate 20 through the adhesive 44 and the support 62 is adhered with the dielectric dam 40. In some embodiments, the support 62 includes a platform portion 62A substantially horizontally extending over the circuit substrate 20 and surrounding the package unit 10, and a wall portion 62B joined with the platform portion 62A and attached to the adhesive 44. In some embodiments, the platform portion 62A and the wall portion 62B are formed integrally. As seen in FIG. 3, the wall portion 62B disposed at the outer periphery of the platform portion 62A extends substantially vertically to connect with the adhesive 44 on the top surface 20T of the circuit substrate 20. In some embodiments, the outer periphery of the support 62 substantially matches the footprint of the circuit substrate 20. In some embodiments, the ring-shaped platform portion 62A of the support 62 has at least an opening OP1 exposing the backside surface 10T of the package unit(s) 10. In some embodiments, the support 62 may have one large central opening for exposing all the underlying package units. In some embodiments, the support 62 has multiple openings in the platform portion 62A respectively exposing the underlying corresponding package units. For example, the support 62 may be made of a thermally conductive metallic material, such as stainless steel, copper (Cu), aluminum, gold, nickel, alloys thereof, or combinations thereof. In some embodiments, the support 62 may be formed by stamping, puncture and then subjected to an anodization or passivation treatment (e.g., with nickel) to enhance its environmental resistance before it is installed on the circuit substrate 20.

Referring to FIG. 3, as the dielectric dam 40 is higher than the package unit, there is a gap G1 between the backside surface 10T of the package unit 10 and the support 62 joined directly onto the dielectric dam 40. Herein, through the dielectric dam 40 abutting the sidewalls 10S of the package unit 10 and the support 62 disposed on the dielectric dam 40, a space is defined for accommodating the to-be-formed thermal interface material (TIM).

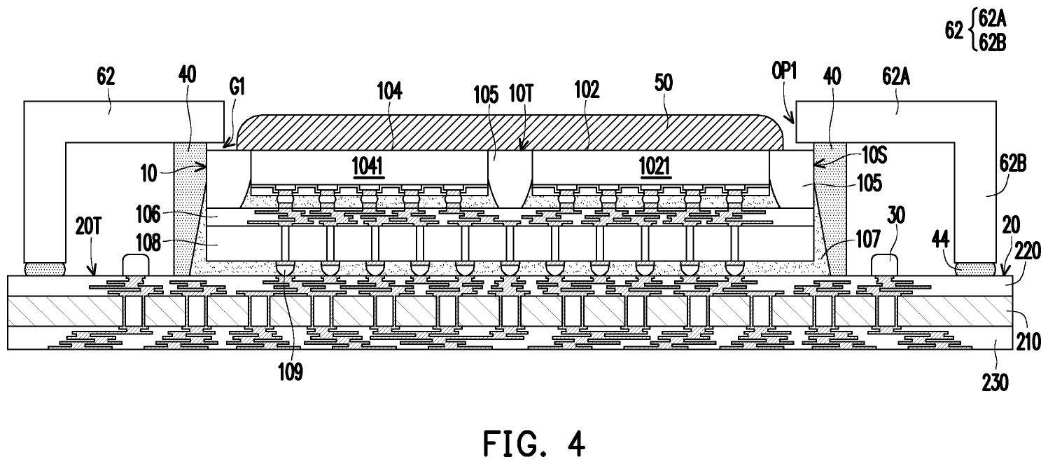

Referring to FIG. 4, in some embodiments, a thermal interface material (TIM) 50 is disposed on the backside surface 10T of the package unit 10, in contact with the backside surfaces of the semiconductor dies 102, 104 and the backside surface of the encapsulant 105. In some embodiments, the TIM 50 extends over most of the backside surface 10T covering the backside surfaces of the semiconductor dies 102, 104 and a portion of the backside surface of the encapsulant 105. In some embodiments, the TIM 50 includes or is a metal-type thermal interface material (metal-TIM), which includes only metals or metal alloys (without containing polymeric materials) and is highly thermally conductive.

According to the embodiments of this disclosure, different types of metal-type thermal interface materials (metal-TIMs) are suitable to be used as TIM 50, including solid type metal-TIMs (SMT) and liquid type metal-TIMs (LMT). Compared with gel-type thermal interface materials or film-type thermal interface materials (containing polymer base materials), the metal-TIMs have much higher thermal conductivity and much lower thermal resistance. For example, the metal-TIMs may have about thermal conductivity ten times higher than the gel-type thermal interface materials. Also, compared with the solder materials, the metal TIMs that are easily adhered to the semiconductor material or dielectric material without using wetting agents and may be cured at lower temperatures offer better processing capability. As seen in Table 1, SMT and LMT may be categorized based on the phase/physical state of the material during semiconductor processing. Also, LMT may be further categorized based on the physical state of the material provided under the room temperature (RT) as liquid state (l) LMT (denoted as LMT(l)) and solid state(s) LMT (denoted as LMT(s)). During the curing process about or higher than the phase change temperature, either SMT or LMT turns into the liquid phase and becomes flowable to fill the space or cavity.

TABLE 1

| | | Incoming | | After curing | During product |
|---|---|---|---|---|---|
| Stage | | (RT) | Curing | back to RT | processing |
| Material | LMT (l) | Liquid | Liquid | Liquid | Liquid |
| Phase | LMT(s) | Solid | Liquid | Solid | Liquid |
| | SMT | Solid | Liquid | Solid | Solid |

For example, LMT(l) includes pure gallium, and indium alloys such as 62.5Ga-21.5In-16.0Sn. 62.5Ga-21.5In-16Sn or 61.0Ga-25.0In-13.0Sn-1.0Zn. For example, LMT(s) includes indium-bismuth alloys such as 51In-32.5Bi-16.5Sn. For example, SMT includes pure indium or indium alloys such as 97In-3Ag.

In some embodiments, as seen in FIG. 4, the TIM 50 is applied onto the backside surface 10T exposed by the opening OP1. In some embodiments, the TIM 50 includes or is a SMT or LMT(s) and is applied in solid form as a film with a suitable thickness on the backside surface 10T. In some other embodiments, the TIM 50 includes or is an LMT(l), the TIM 50 is applied directly on the backside surface 10T, and the platform portion 62A and the dielectric dam 40 can restrain the outflow of the TIM 50. In some embodiments, the TIM 50 includes one or more metals from tin (Sn), gallium (Ga), indium (In), bismuth (Bi), zinc (Zn), silver (Ag) or other suitable thermally conductive metals. In some embodiments, the TIM 50 includes gallium, gallium alloys, gallium-indium-tin alloys, gallium-indium-tin-zinc alloys, indium-bismuth-tin alloys. According to the type of material used, the TIM 50 may be formed by deposition, lamination, printing, plating, or any other suitable technique. As seen in FIG. 4, the TIM 50 is disposed within the opening OP1 in an amount sufficient to cover the backside surfaces of the semiconductor dies 102, 104 without filling up the opening OP1. Taking the TIM formed as a solid or semi-solid film as an example, the span of the TIM 50 is smaller than the span of the opening OP1, so that the TIM 50 has not filled into the gap G1. Taking the TIM applied in the liquid phase as an example, the amount of the TIM 50 is not enough to fill up the opening OP1 but the TIM 50 may flow into and fill into the gap G1.

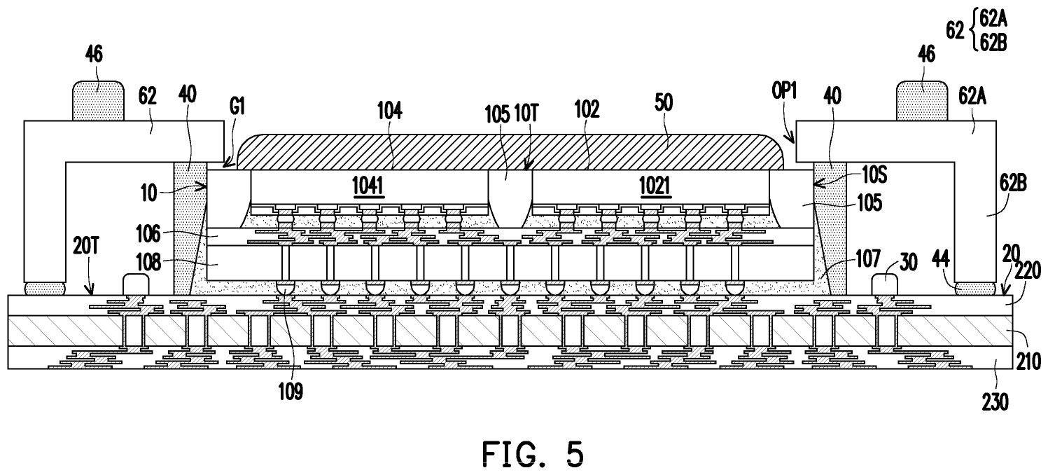

Referring to FIG. 5, an adhesive material 46 is applied and disposed on the top surface of the platform portion 62A of the support 62. In some embodiments, the adhesive material 46 includes or is a thermo-curable adhesive, a photocurable adhesive, a thermally conductive adhesive, a thermosetting resin, a waterproof adhesive, a lamination adhesive, or a combination thereof. According to the type of material(s) used, the adhesive material 46 may be formed by dispensing, lamination, printing, or any other suitable technique. In some embodiments, the material of the adhesive material 46 is different from the material of the adhesive 44 or the material of the dielectric dam 40. In one embodiment, the materials of the adhesive material 46 and the adhesive 44 are the same.

Referring to FIG. 6 and FIG. 7A, a metallic cover 64 is aligned and mounted onto the support 62. Later, a curing process is performed and the TIM 50 becomes TIM 52. After the curing process, the metallic cover 64 is fixed onto the support 62 through the adhesive material 46 and the TIM 52. In some embodiments, the metallic cover 64 includes a lid portion 64A and a flange portion 64B extending outward from the lid portion 64A. In some embodiments, the lid portion 64A and the flange portion 64B are integrally formed, and a thickness Tl of the lid portion 64A is larger than a thickness of the flange portion 64B. When the metallic cover 64 is aligned with the support 62, the lid portion 64A is aligned to and inserted into the opening OP1, but the lid portion 64A is spaced apart from the opening sidewalls with a distance T4 (without touching the opening sidewalls) because the span of the lid portion 64A is smaller than the opening size. Through the arrangement, some space is left for accommodating the flowable TIM during the curing process.

In some embodiments, the metallic cover 64 may be made of a thermally conductive metallic material, such as stainless steel, copper, aluminum, gold, nickel, alloys thereof, or combinations thereof. In some embodiments, the metallic cover 64 may be formed by mechanical stamping and then subjected to an anodization or passivation treatment (e.g., with nickel) to enhance its environmental resistance before it is installed on the circuit substrate 20.

In some embodiments, when the metallic cover 64 is mounted and pressed onto the support 62, the lid portion 64A is disposed over the package unit 10 in contact with the TIM 50, and the flange portion 64B located at the edge of the lid portion 64A is in contact with the adhesive material 46. In some embodiments, a curing process is performed while pressing, and during curing, the adhesive material 46 is distributed between the flange portion 64B and the platform portion 62A. In some embodiments, the curing process is performed under the temperature ranging from about 100 degrees Celsius to about 200 degrees Celsius, preferably from about 130 degrees Celsius to about 180 degrees Celsius. Depending on the types of TIM(s) used, the curing temperature may be tuned, and the metal-TIM turns into the liquid state and becomes flowable during the curing process. Due to the liquifying property or the phase change property of the TIM 50, the TIM 50 becomes flowable during curing and fills up the space between the support 62, the metallic cover 64 and the package unit 10, filling up the gap G1 as well.

After curing, by filling up the space between the support 62, the metallic cover 64 and the package unit 10, the cured TIM 52 includes a base portion 52B, a brim portion 52A joined with and surrounding the base portion 52B and an extended portion 52C projected outwardly from the base portion 52B, as seen in FIG. 6 and FIG. 7A. In some embodiments, the TIM 52 is formed into a tray shaped or basin shaped structure as shown in FIG. 7D. In some embodiments, the base portion 52B and the extended portion 52C are disposed directly on the backside surface 10T and fully cover the backside surface 10T of the package unit 10 and extend substantially parallel to the circuit substrate 20. Due to the flowability of the TIM, the coverage of the TIM 52 (the base portion 52B) over the backside surface 10T of the package unit 10 is excellent, achieving 90% or even up to 95% coverage. In some embodiments, the brim portion 52A extend in a direction substantially perpendicular to the plane defined by the base portion 52B. In some embodiments, the brim portion 52A, the base portion 52B and the extended portion 52C are integrally formed. That is, the brim portion 52A, the base portion 52B and the extended portion 52C jointed to each other without a clear interface between the two. In some embodiments, as the cured adhesive material 43 may have a curved surface, the contact interface between the cured TIM 52 and the adhesive material 46 may have a curved profile (see FIG. 7A).

In FIG. 7A and FIG. 7B, in some embodiments, the base portion 52B that is sandwiched between the lid portion 64A and the backside surface 10T has a thickness T3. In some embodiments, the base portion 52B extending over the backside surface 10T of the package unit has a uniform thickness T3, which is beneficial for heat transfer from the backsides of the semiconductor dies. In some embodiments, the thickness T3 is determined by the distance left between the lid portion 64A and the backside surface 10T of the package unit 10, which may be predetermined by calculating the amount of the adhesive material 46 (directly related to the thickness of the cured adhesive material 46) and arranging the height difference between the lower surface of the platform portion 62A and the backside surface 10T. Referring to FIG. 7A, the brim portion 52A that is sandwiched between the sidewalls of the lid portion 64A and the sidewalls of the platform portion 62A and the adhesive material 46 has a thickness T4 (determined by the distance left between the lid portion 64A and the platform portion 62A. Also, the extended portion 52C filled up the gap G1 has a thickness T5. In some embodiments, the thickness T3 is at least equivalent to or larger than the thickness T4, the thickness T4 is larger than the thickness T5.

Referring to FIG. 7A, FIG. 7B and FIG. 7C, the TIM 52 fully covers the package unit 10 (fully covering the whole backside surface 10T). From the top view of FIG. 7B, the span of the TIM 52 is substantially the same as the span of the package unit 10. From FIG. 7B, in some embodiments, the wall portion 62B of the support 62 is spaced apart from the dielectric dam 40 but encloses the dielectric dam 40 and the package unit 10. Referring to FIG. 7A and FIG. 7B, the dielectric dam 40 abuts the TIM 52 and encircles the package unit 10. As shown in FIG. 7C, the brim portion 52A of the TIM 52 is in contact with and encircles the lid portion 64A, while the platform portion 62A is in contact with and encircles the brim portion 52A.

In some embodiments, the TIM 52 is filled inside the enclosed space defined by the metallic cover 64, the backside of the package unit 10, the platform portion 62A, the dielectric dam 40 and the adhesive material 46, so that overflow or overspill of the TIM 52 is avoided. Referring to FIG. 6, in some embodiments, the dielectric dam 40 is in contact with the sidewalls 10S of the package unit 10 and surrounding the package unit 10 on all sides. That is, the package unit 10 is fully enclosed by the dielectric dam 40 and is contained with the support 62.

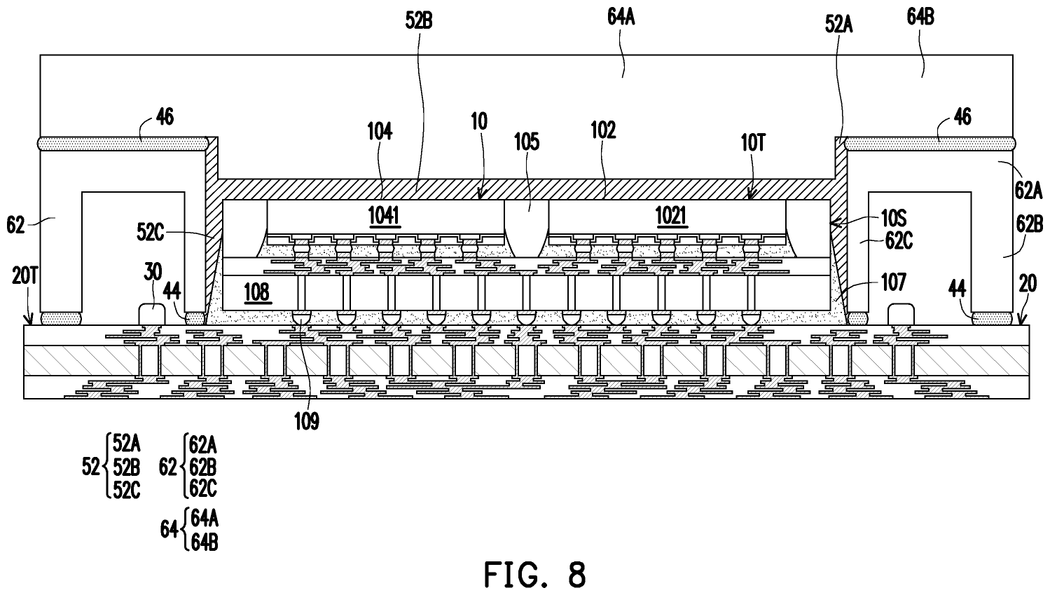

FIG. 8 is a schematic cross-sectional view of a semiconductor package according to some embodiments of the present disclosure. In some alternative embodiments, instead of forming the dielectric dam 40, the support 62 further includes rib wall portions 62C joined with the platform portion 62A and extending substantially vertically from the platform portion 62A downward toward the circuit substrate 20. In some embodiments, when the support 62 is placed onto the adhesive 44 over the circuit substrate 20, the rib wall portions 62 are disposed between the package unit 10 and the passive components 30. After the thermal process, the support 62 (including the rib wall portions 62C) is fixed to the circuit substrate 20 through the adhesive 44. In some embodiments, the rib wall portions 62C are disposed between the passive components 30 and the underfill 107 surrounding the package unit as a stopper for blocking and separating the later flowable TIM.

Referring to FIG. 8, in some embodiments, following the curing process, the TIM 52 is filled between the metallic cover 64, the package unit 10, the rib wall portions 62C, the adhesive material 46 and the adhesive 44. In some embodiments, the TIM 52 includes the brim portion 52A joined to the base portion 52B, and the extended portion 52C joined with the base portion 52B. Similarly, the brim portion 52A surrounds the base portion 52B and extends upward from the base portion 52B. In some embodiments, the extended portion 52C projects from the base portion 52B and extends downward toward the circuit substrate 20, as seen in FIG. 8. In some embodiments, the TIM 52 is formed into a reverse basin shaped or reverse bowl-shaped structure. In some embodiments, the base portion 52B and the extended portion 52C are in direct contact with the backside surface 10T and the sidewalls 10S of the package unit 10, and fully cover the whole backside surface 10T and upper portions of the sidewalls 10S of the package unit 10. In some embodiments, the extended portion 52C is sandwiched between the rib wall portions 62C and the underfill 107 and between the sidewalls 10S and the rib wall portions 62C. In some embodiments, the extended portion 52C extends to reach the circuit substrate 20 and is sandwiched between the adhesive 44, the underfill 107 and the circuit substrate 20.

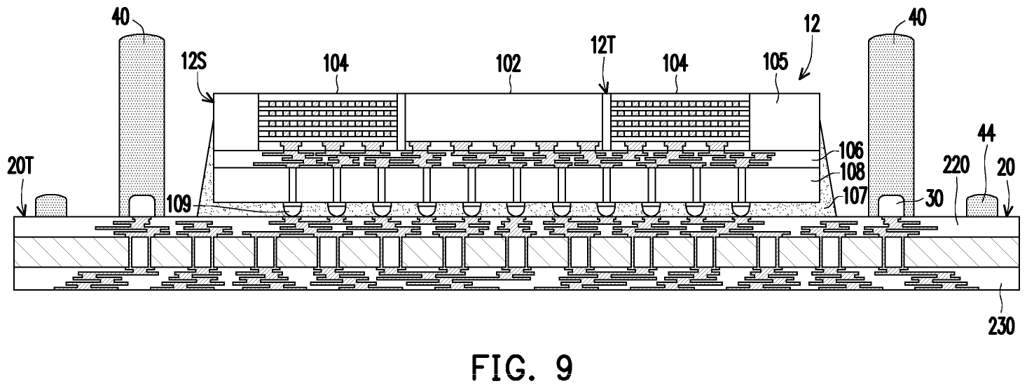

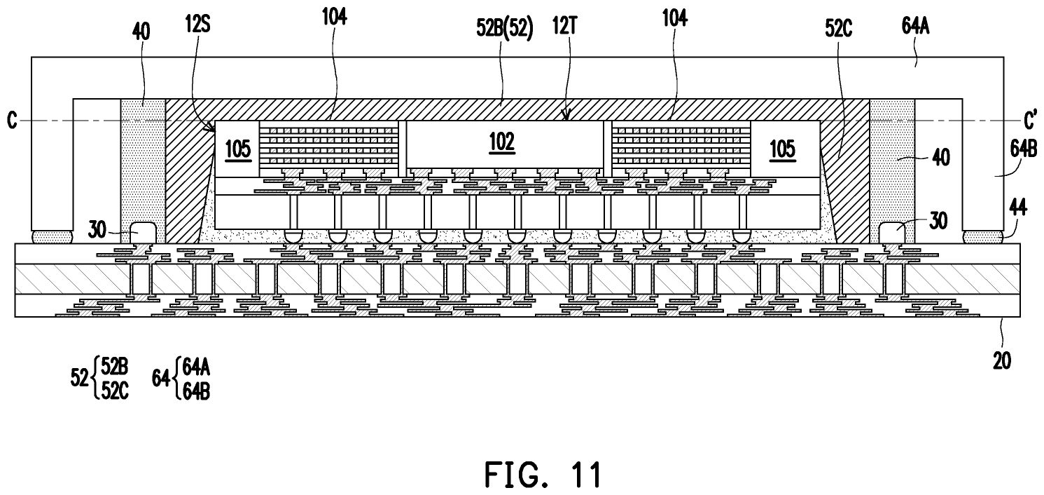

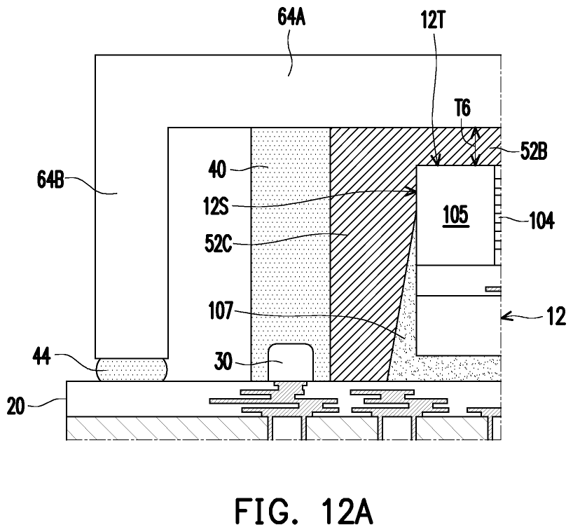

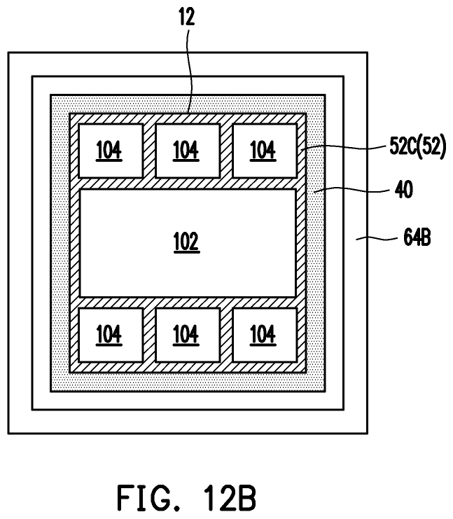

FIG. 9 to FIG. 11 are schematic cross-sectional views of structures produced at various stages of a manufacturing method of a semiconductor package according to some embodiments of the present disclosure. FIG. 12A is a schematic cross-sectional view of a portion of the semiconductor package as shown in FIG. 11. FIG. 12B is a schematic top view of the semiconductor package of FIG. 11 along the cross-section lines C-C′. Similar or substantially the same structural parts or elements may be labelled with similar or the same reference numbers for illustration purposes.

Referring to FIG. 9, in some embodiments, one or more package units 12 (only one is shown) are mounted onto and connected to the top surface 20T of the circuit substrate 20, and a plurality of passive components 30 are mounted onto and bonded to the top surface 20T of the circuit substrate 20 and beside the package unit(s) 12. In some embodiments, the passive components 30 include or are capacitors, inductors, resistors, diodes, transformers or combinations thereof. In some embodiments, the package unit 12 includes or is a chip-on-wafer-on-substrate (CoWoS) package, and the package unit 12 is bonded to and electrically connected with the circuit substrate 20 through the electrical connectors 109. In some embodiments, the package unit 12 includes more than three semiconductor dies, and one semiconductor die 102 and two semiconductor dies 104 are shown in the cross-sectional view of the figure as an example. In some embodiments, the semiconductor dies 102, 104 may independently be or include a logic die, such as a CPU die, a GPU die, a MCU die, a I/O die, a BB die, a SoC die, a LSI die, or an AP die, or memory dies such as HBM dies. In some embodiments, the semiconductor die 102 includes or is a SoC die and the semiconductor dies 104 include or are HBM dies. The disclosure is not limited by the types of dies included in the package unit 10.

Referring to FIG. 9, an encapsulant 105 is formed over the redistribution layer 106 and the interposer 108 wrapping the semiconductor dies 102, 104. In some embodiments, the semiconductor dies 102, 104 are disposed with the active surfaces facing the interposer 108 and are bonded to the redistribution layer 106. In some embodiments, the encapsulant 105 laterally encapsulated the semiconductor dies 102, 104 leaving the backside surfaces of the semiconductor dies 102, 104 exposed. That is, the backside surface 12T of the package unit 12 is constituted by the backside surfaces of the semiconductor dies 102, 104 and the encapsulant 105. In some embodiments, the electrical connectors 109 disposed between the package unit(s) 12 and the circuit substrate 20 include or are C4 bumps. In some embodiments, another underfill 107 is disposed between the package unit 12 and the circuit substrate 20 to protect the connectors 109 from thermal and mechanical stresses and securing the package unit(s) 12.

Referring to FIG. 9, in some embodiments, an adhesive 44 is applied and disposed on the top surface 20T of the circuit substrate 20, along the outer periphery of the circuit substrate 20. In some embodiments, a dielectric dam 40 is formed beside the package unit 12 and covers the passive components 30. In some embodiments, the dielectric dam 40 is formed beside and spaced apart from the package unit 12 with a distance. In FIG. 9, in some embodiments, the dielectric dam 40 fully covers the passive components 30 without touching the underfill 107 or the sidewalls 12S of the package unit 12. In some embodiments, the dielectric dam 40 has a height larger than the package unit 12, or the top of the dielectric dam 40 is higher than the backside surface 12T of the package unit 12. In some embodiments, the dielectric dam 40 forms a continuous frame wall surrounding the profile of the outer periphery of the package unit 12 (e.g. in FIG. 12B). The dielectric dam 40 may function to limit the distribution and span of the to-be-formed thermal interface material (TIM) and protect the passive components. Also, the dielectric dam 40 located beside the package unit 12 fully wraps the passive components 30 and physically isolates the passive components 30 from the later formed TIM. The formation methods and materials of the adhesive 44 and dielectric dam 40 are similar to the methods and materials described in previous paragraphs, and will not be repeated for simplicity.

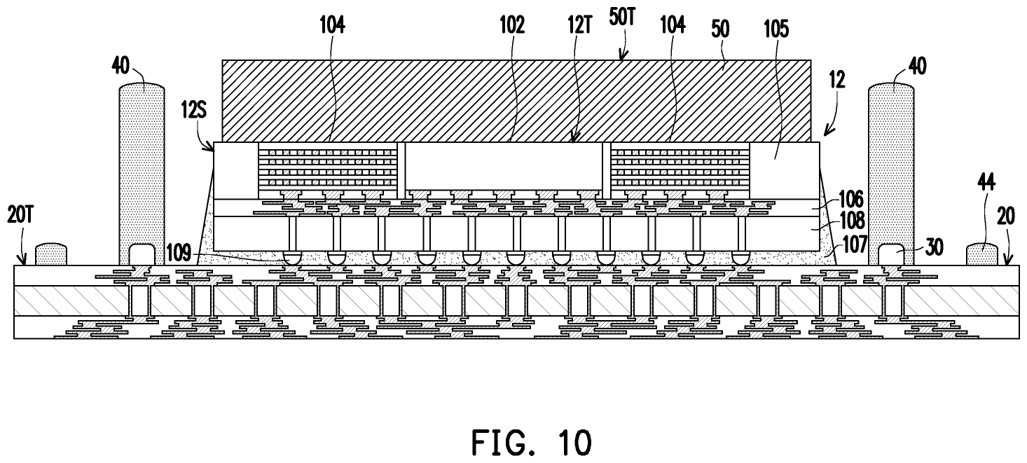

In some embodiments, as seen in FIG. 10, the TIM 50 is applied onto the backside surface 12T of the package unit 12. In some embodiments, the TIM 50 includes or is a SMT or LMT(s) and is applied in solid form as a film with a suitable thickness on the backside surface 12T. In some embodiments, the TIM 50 includes one or more metals from tin (Sn), gallium (Ga), indium (In), bismuth (Bi), zinc (Zn), silver (Ag) or other suitable thermally conductive metals. In some embodiments, the TIM 50 includes gallium, gallium alloys, gallium-indium-tin alloys, gallium-indium-tin-zinc alloys, indium-bismuth-tin alloys. According to the type of material used, the TIM 50 may be formed by deposition, lamination, printing, plating, or any other suitable technique. As seen in FIG. 10, the TIM 50 is applied with an amount (or thickness) sufficient to cover the backside surfaces of the semiconductor dies 102, 104. Taking the TIM formed as a solid or semi-solid film as an example, the span of the TIM 50 is smaller than the span of the backside surface 12T, and the top surface 50T of the applied TIM 50 on the backside surface 12T is higher than the top of the dielectric dam 40.

Referring to FIG. 11, a metallic cover 64 is mounted onto the adhesive 44 over the circuit substrate 20, and the metallic cover 64 touches the TIM 50 and the dielectric dam 40. Later, a curing process is performed and the TIM 50 becomes TIM 52. After the curing process, the metallic cover 64 is fixed onto the circuit substrate 20 through the adhesive 44 and connected with the package unit 12 through the TIM 52. In some embodiments, the metallic cover 64 includes a lid portion 64A and a flange portion 64B extend in a direction substantially perpendicular to the plane defined by the lid portion 64A. In some embodiments, the lid portion 64A and the flange portion 64B are integrally formed and have substantially the same thickness. When the metallic cover 64 is placed over the circuit substrate 20, the lid portion 64A is pressed against and touches the TIM 50 and the dielectric dam 40, and the flange portion 64B located at the edge of the lid portion 64A is in contact with the adhesive 44 without touching the dielectric dam 40. Since the span of the lid portion 64A is larger than the package unit 12 and the distribution region of the dielectric dam 40, some space is defined for accommodating the flowable TIM. Through the arrangement, the flowable TIM during the curing process fills up the space between the package unit 12, the dielectric dam 40 and the metallic cover 64.

After curing, by filling up the space between the metallic cover 64, the dielectric dam 40 and the package unit 12, the cured TIM 52 fully covers and substantially encapsulates the package unit 12 and the underfill 107. In some embodiments, the TIM 52 includes a base portion 52B and an extended portion 52C joined with the base portion 52B and surrounding the base portion 52B, and the extended portion 52C projected downward from the base portion 52B, as seen in FIG. 11 and FIG. 12A. In some embodiments, the TIM 52 is formed into a reverse basin shaped or reverse bowl-shaped structure. In some embodiments, the base portion 52B is disposed directly on the backside surface 12T and fully cover the backside surface 12T of the package unit 12 and extend substantially parallel to the circuit substrate 20. In some embodiments, the extended portion 52C is in contact with the sidewalls 12S and the underfill 107, and covers portions of the sidewalls 12S and the underfill 107. Due to the flowability of the TIM, the base portion 52B extending over the backside surface 12T of the package unit 12 has a uniform thickness T6, which is beneficial for heat transfer from the backsides of the semiconductor dies. Also, the coverage of the TIM 52 (especially the base portion 52B) over the backside surface 12T of the package unit 12 is excellent, achieving 90% or even up to 95% coverage. In some embodiments, the extended portion 52C extend in a direction substantially perpendicular to the plane defined by the base portion 52B. In some embodiments, the base portion 52B and the extended portion 52C are integrally formed (i.e. jointed to each other without a clear interface between the two).

As shown in FIG. 12A and FIG. 12B, the dielectric dam 40 encloses the package unit 12 and the TIM 52, the TIM 52 fully covers the package unit 12, and the extended portion 52C of the TIM 52 is in direct contact with and sandwiched between the dielectric dam 40 and the sidewalls 12S and the underfill 107. In one embodiment, the package unit 12 includes one semiconductor die 102 and six semiconductor dies 104, in FIG. 12B.

In some embodiments, when the underfill 107 partially covers the sidewalls 12S of the package unit 12, the later formed extended portion 52C may be in contact with the sidewalls of the package unit 10. In some embodiments, depending on the relative configurations of the underfill 107 and the dielectric dam 40, the extended portion 52 sandwiched there-between may be in contact with or not in contact with the circuit substrate 20.

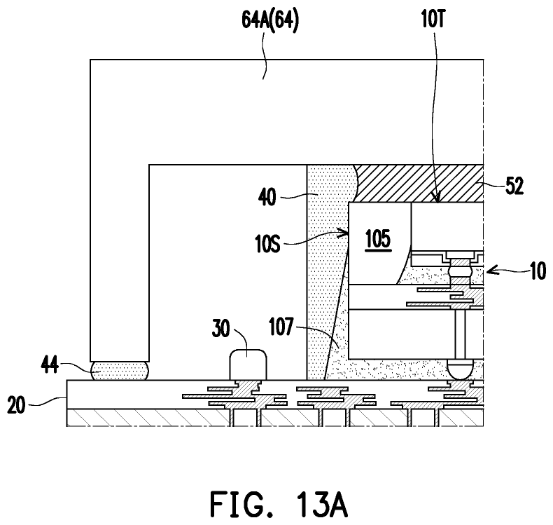

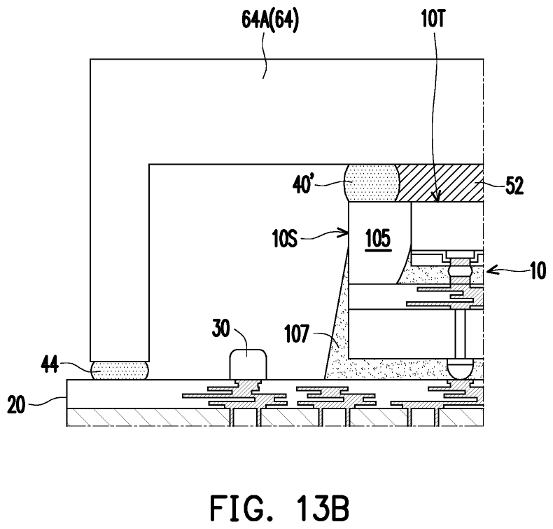

FIG. 13A and FIG. 13B are schematic cross-sectional views of portions of semiconductor packages according to some embodiments of the present disclosure. Different arrangements and configurations of the metallic cover and the dielectric dam may change the location of the cured TIM.

Referring to FIG. 13A, in some embodiments, the dielectric dam 40 is formed on the circuit substrate 20 along the outer periphery of the package unit 10 and beside the passive components 30 (spaced apart from the passive components 30). In FIG. 13A, in some embodiments, the top of the dielectric dam 40 is higher than the backside surface 10T of the package unit 10, the dielectric dam 40 contacts and covers the underfill 107 and the sidewalls 10S of the package unit 10. In some embodiments, the dielectric dam 40 forms a continuous frame wall following the profile of the outer periphery of the package unit 10. As the dielectric dam limits the distribution and span of the TIM 52, the formed TIM 52 is sandwiched between the metallic cover 64 (the lid portion 64A), the dielectric dam 40 and the backside surface 10T of the package unit 10. That is, the TIM 52 covers substantially the whole backside surface 10T of the package unit 10. Also, the dielectric dam 40 physically separates the package unit 10 and the TIM 52 from the passive components 30.

Referring to FIG. 13B, in some embodiments, the dielectric dam 40′ is formed directly on the backside surface 10T of the package unit 10 along the outer periphery of the package unit 10. The TIM 52 is limited by the metallic cover 64, the package unit 10 and the dielectric dam 40′, and is sandwiched between the metallic cover 64 (the lid portion 64A), the package unit 10 and the dielectric dam 40′. Due to the existence of the dielectric dam 40′, the span of the TIM 52 is smaller than the span of the package unit 10. In some embodiments, as the dielectric dam 40 or 40′ may have a curved surface, the contact interface between the cured TIM 52 and the dielectric dam 40 or 40′ may have a curved profile.

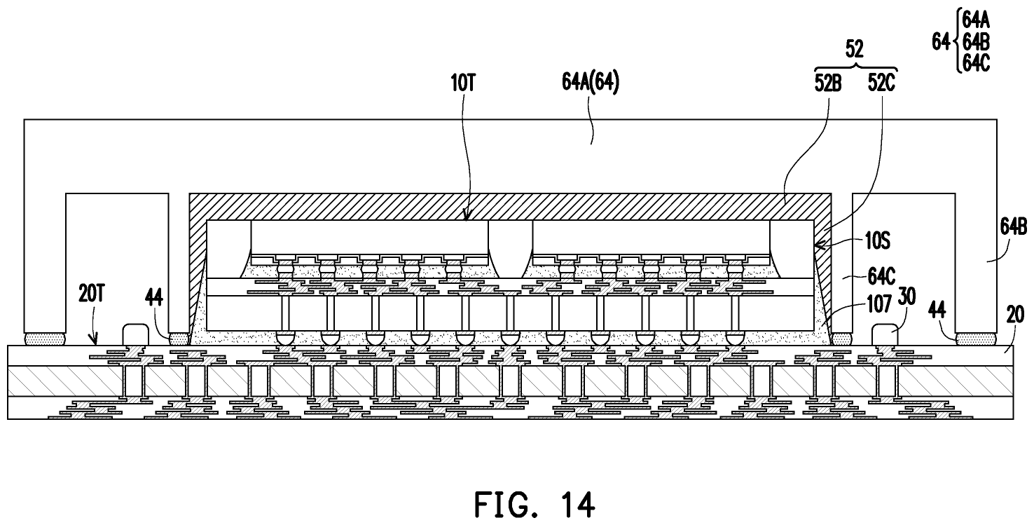

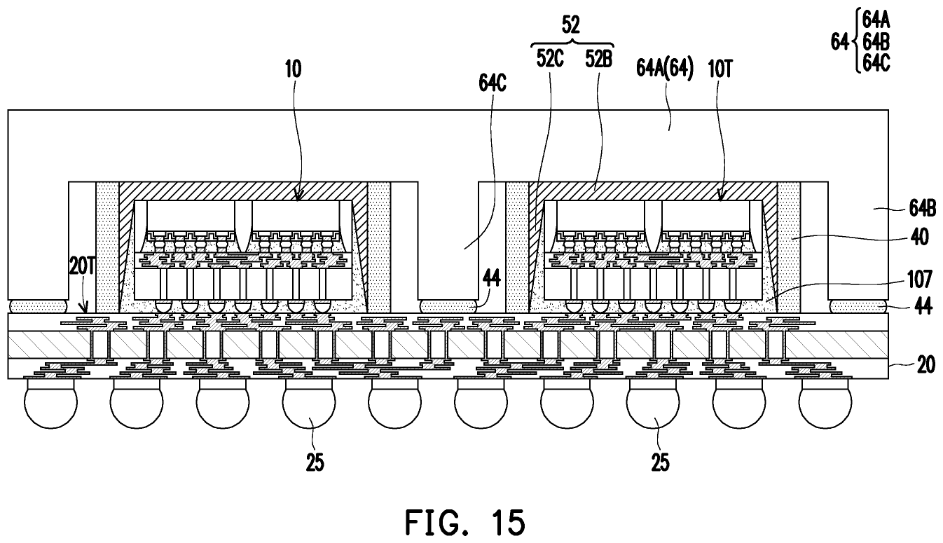

FIG. 14 and FIG. 15 are schematic cross-sectional views of semiconductor packages according to some embodiments of the disclosure.

Referring to FIG. 14, in some embodiments, the metallic cover 64 further includes rib wall portions 64C joined with the lid portion 64A and extending substantially vertically from the lid portion 64A downward toward the circuit substrate 20. In some embodiments, when the metallic cover 64 is placed onto the adhesive 44 over the circuit substrate 20, the rib wall portions 62 are disposed between the package unit 10 and the passive components 30. After the thermal process, the metallic cover 64 (including the rib wall portions 64C) is fixed to the circuit substrate 20 through the adhesive 44. In some embodiments, the rib wall portions 64C are disposed between the passive components 30 and the underfill 107 surrounding the package unit as a stopper for blocking and separating the later flowable TIM.

Referring to FIG. 14, in some embodiments, following the curing process, the TIM 52 is filled between the lid portion 64A, the package unit 10, the rib wall portions 64C and the adhesive 44. In some embodiments, the TIM 52 includes the base portion 52B and the extended portion 52C joined with the base portion 52B, surrounding the base portion 52B and extends downward from the base portion 52B. In some embodiments, the extended portion 52C projects from the base portion 52B and extends downward toward the circuit substrate 20, as seen in FIG. 14. In some embodiments, the TIM 52 is formed into a reverse basin shaped or reverse bowl-shaped structure. In some embodiments, the base portion 52B is in direct contact with and covers the whole backside surface 10T, and the extended portion 52C is in contact with the sidewalls 10S of the package unit 10 and covers upper portions of the sidewalls 10S of the package unit 10. In some embodiments, the extended portion 52C is sandwiched between the rib wall portions 64C and the underfill 107 and between the sidewalls 10S and the rib wall portions 64C. In some embodiments, the extended portion 52C extends to reach the circuit substrate 20 and is sandwiched between the adhesive 44, the underfill 107 and the circuit substrate 20.

Referring to FIG. 15, in some embodiments, the metallic cover 64 includes at least one rib wall portion 64C joined with the lid portion 64A and extending substantially vertically from the lid portion 64A downward toward the circuit substrate 20. In some embodiments, the rib wall portion 64C segregates the space enclosed by the metallic cover into at least two parts or more parts. In some embodiments, multiple package units 10 (two units are shown) are bonded to the circuit substrate 20, and each package unit 10 bonded to the circuit substrate 20 is secured by the underfill 107 and encircled by the dielectric dam 40. In some embodiments, when the metallic cover 64 is placed onto the adhesive 44 over the circuit substrate 20, the rib wall portion 64C is disposed between the package units 10 and spaced apart from the dielectric dam 40 surrounding each package unit 10. After the thermal process, the metallic cover 64 (including the rib wall portions 64C) is fixed to the circuit substrate 20 through the adhesive 44. In some embodiments, the dielectric dam 40 surrounding the package unit 10 functions as a stopper for limiting the later flowable TIM.

Referring to FIG. 15, in some embodiments, following the curing process, the TIM 52 is filled between the lid portion 64A, the package unit 10, and the dielectric dam 40. In some embodiments, the TIM 52 includes the base portion 52B and the extended portion 52C joined with the base portion 52B, surrounding the base portion 52B and extends downward from the base portion 52B. In some embodiments, the TIM 52 is formed into a reverse basin shaped or reverse bowl-shaped structure. In some embodiments, the base portion 52B is in direct contact with and covers the whole backside surface 10T, and the extended portion 52C is in contact with the underfill 107 around the package unit 10 and covers the underfill 107. In some embodiments, the extended portion 52C is sandwiched between the dielectric dam 40 and the underfill 107. In some embodiments, when the underfill 107 fully covers the sidewalls of the package unit 10, the later formed extended portion 52C is not in contact with the sidewalls of the package unit 10. In some embodiments, depending on the relative configurations of the underfill 107 and the dielectric dam 40, the extended portion 52 sandwiched there-between may be not in contact with the circuit substrate 20.

In some embodiments, connective terminals 25 are formed on the circuit substrate 20 for further electrical connection. In some embodiments, the connective terminals 25 are solder balls for ball grid array mounts. In some embodiments, the connective terminals 25 are electrically connected to the package units 10 via the circuit substrate 20.

According to the embodiments, through the arrangement of the metallic cover and the dielectric dam and/or the support optionally, the metal-TIM having high thermal conductivity and excellent coverage can be used as the first level thermal interface material (thermal interface material on chip or die level) in various package structures. Taking advantage of the liquifying property of the metal-TIM, the metal-TIM during curing can sufficiently fills up the space and gap between the dies and the cover and achieves excellent uniform coverage over the dies of the package structures. Furthermore, the cured metal-TIM is spaced apart from the passive components through either the dielectric dam or the rib wall portions, avoiding undesirable shortage cause by TIM overflow.

In accordance with some embodiments of the disclosure, a package structure is provided. The package structure includes a circuit substrate, a package unit, a thermal interface material and a cover. The package unit is disposed on the circuit substrate and electrically connected to the circuit substrate. The package unit includes a first surface facing the circuit substrate and a second surface opposite to the first surface and away from the circuit substrate. A underfill is disposed between the package unit and the circuit substrate, surrounding the package unit and partially covering sidewalls of the package unit. The cover is disposed over the package unit and over the circuit substrate and is connected to the circuit substrate. A first adhesive is disposed on the circuit substrate and between the cover and the circuit substrate. The thermal interface material is disposed between the cover and the package unit. The thermal interface material physically contacts the second surface and the sidewalls of the package unit and physically contacts the underfill, and the thermal interface material includes metal.

In accordance with some embodiments of the disclosure, a package structure includes a circuit substrate, a package unit, a thermal interface material, a dielectric dam and a cover. The package unit is disposed on the circuit substrate and electrically connected to the circuit substrate. The package unit includes a first surface facing the circuit substrate and a second surface opposite to the first surface and away from the circuit substrate. The cover is disposed over the package unit and over the circuit substrate and is connected to the circuit substrate. A first adhesive is disposed on the circuit substrate and between the cover and the circuit substrate. The thermal interface material is disposed between the cover and the package unit and on the second surface. The dielectric dam is disposed between the cover and the package unit. The thermal interface material physically contacts the dielectric dam, the cover and the second surface of the package unit.

In accordance with some embodiments of the disclosure, a manufacturing method including the following steps is provided. A package unit is bonded to a circuit substrate. The package unit is electrically connected with the circuit substrate and has a first surface facing the circuit substrate and a second surface opposite to the first surface and away from the circuit substrate. An adhesive is formed on the circuit substrate. A dielectric dam is formed on the circuit substrate and spaced apart from the adhesive and around the package unit. A thermal interface material is formed on the second surface of the package unit. A cover is mounted and secured over the adhesive on the circuit substrate. A curing process is performed to cure the thermal interface material. The thermal interface material physically contacts the dielectric dam, the cover and the second surface of the package unit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a circuit substrate,
a package unit, disposed on the circuit substrate and electrically connected to the circuit substrate, wherein the package unit includes a first surface facing the circuit substrate and a second surface opposite to the first surface and away from the circuit substrate;
an underfill, disposed between the package unit and the circuit substrate, surrounding the package unit and partially covering sidewalls of the package unit;
a cover, disposed over the package unit and over the circuit substrate;
a first adhesive, disposed on the circuit substrate and between the cover and the circuit substrate; and
a thermal interface material disposed between the cover and the package unit, wherein the thermal interface material physically contacts the second surface and the sidewalls of the package unit and physically contacts the underfill, and the thermal interface material includes metal.

2. The structure of claim 1, wherein the cover includes a lid portion and rib wall portions extending from the lid portion and abutting the thermal interface material surrounding the package unit, and the rib wall portions are connected to the circuit substrate through the first adhesive.

3. The structure of claim 2, wherein the thermal interface material includes a base portion covering the second surface of the package unit and an extended portion joined with the base portion and sandwiched between the rib wall portions and the underfill and the sidewalls of the package unit.

4. The structure of claim 1, further comprising a support disposed between the cover and the circuit substrate.

5. The structure of claim 4, further comprising a second adhesive disposed between the cover and the support, the support is connected to the circuit substrate through the first adhesive, and the cover is connected with the support through the second adhesive.

6. The structure of claim 5, wherein the support includes a platform portion and rib wall portions extending from the platform portion and abutting the thermal interface material surrounding the package unit, and the rib wall portions are connected to the circuit substrate through the first adhesive.

7. The structure of claim 6, wherein the thermal interface material includes a base portion covering the whole second surface of the package unit and an extended portion joined with the base portion and sandwiched between the rib wall portions and the underfill and the sidewalls of the package unit.

8. The structure of claim 7, wherein the thermal interface material includes a brim portion joined with and extending from the base portion and sandwiched between the cover, the second adhesive and the support.

9. The structure of claim 1, further comprising a dielectric dam surrounding the package unit and physically contact the thermal interface material.

10. The structure of claim 1, further comprising passive components bonded to the circuit substrate, wherein the thermal interface material is spaced apart from the passive components.

11. A package structure, comprising:
a circuit substrate,
a package unit, disposed on the circuit substrate and electrically connected to the circuit substrate, wherein the package unit includes a first surface facing the circuit substrate and a second surface opposite to the first surface and away from the circuit substrate;
a cover, disposed over the package unit and over the circuit substrate, wherein the cover is connected to the circuit substrate;
a first adhesive, disposed on the circuit substrate and between the cover and the circuit substrate;
a thermal interface material, disposed between the cover and the package unit and on the second surface; and
a dielectric dam disposed between the cover and the package unit, wherein the thermal interface material physically contacts the dielectric dam, the cover and the second surface of the package unit.

12. The structure of claim 11, further comprising an underfill, disposed between the package unit and the circuit substrate, surrounding the package unit and partially covering sidewalls of the package unit.

13. The structure of claim 11, wherein the cover includes a lid portion and a flange portion and rib wall portions extending from the lid portion, the flange portion and the rib wall portions are connected to the circuit substrate through the first adhesive, and the rib wall portions abut the thermal interface material surrounding the package unit.

14. The structure of claim 13, wherein the thermal interface material includes a base portion covering the whole second surface of the package unit and an extended portion joined with the base portion and sandwiched between the rib wall portions and the underfill and the sidewalls of the package unit.

15. The structure of claim 11, further comprising a support disposed between the cover and the circuit substrate and a second adhesive disposed between the cover and the support, wherein the support is connected to the circuit substrate through the first adhesive, and the cover is connected with the support through the second adhesive.

16. The structure of claim 15, wherein the support includes a platform portion and a wall portion extending from the platform portion and abutting the thermal interface material surrounding the package unit, and the rib wall portions are connected to the circuit substrate through the first adhesive.

17. The structure of claim 16, wherein the thermal interface material includes a base portion covering the second surface of the package unit, a brim portion joined with and extending from the base portion and sandwiched between the cover, the second adhesive and the support, and an extended portion joined with the base portion and sandwiched between the dielectric dam, the support and the package unit.

18. A manufacturing method of a semiconductor structure, comprising:
bonding a package unit to a circuit substrate, wherein the package unit is electrically connected with the circuit substrate and has a first surface facing the circuit substrate and a second surface opposite to the first surface and away from the circuit substrate;
forming an adhesive on the circuit substrate;
forming a dielectric dam on the circuit substrate and spaced apart from the adhesive and around the package unit;
forming a thermal interface material on the second surface of the package unit;
mounting and securing a cover over the adhesive on the circuit substrate; and
performing a curing process to cure the thermal interface material, wherein the thermal interface material physically contacts the dielectric dam, the cover and the second surface of the package unit.

19. The manufacturing method of claim 18, further comprising forming an underfill between the package unit and the circuit substrate after bonding the package unit to the circuit substrate.

20. The manufacturing method of claim 18, wherein the thermal interface material includes a metal-type thermal interface material.
